(19) United States
(12) Patent Application Publication
(10) Pub. No.: US 2003/0190771 A1
(43) Pub. Date: Oct. 9, 2003

(54) Integrated ram and non-volatile memory cell method and structure

(75) Inventor: Kyu Hyun Choi, Cupertino, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: 02IC, Ltd., Seoul (KR); 02IC, Inc., Cupertino, CA

(21) Appl. No.: 10/093,752

(22) Filed: Mar. 7, 2002

(51) Int. Cl. G11C 11/34

(52) U.S. Cl. 438/200

(57) ABSTRACT

In accordance with the present invention, a memory cell includes both non-volatile and SRAM cells. The non-volatile memory cell includes two MNOS transistors forming a differential pair. The SRAM cell includes a pair of MOS select transistors and a pair of cross-coupled MOS transistors. The MOS select transistors are adapted to couple the true and complement bitlines associated with the memory cell to various terminals of the cross-coupled MOS transistors, thereby to load data into the SRAM. During power-off, data is loaded from the SRAM into the non-volatile memory cell. During a subsequent read of the non-volatile memory cell, the SRAM is reloaded with data it had prior to the power-off. Because the MNOS transistors of the non-volatile memory cell operate differentially, data read errors caused by over-erase are reduced. Because the voltages applied during programming and erase cycle of the non-volatile memory cell are relatively small, the memory cell consumes relatively small amount of power.

### BACKGROUND OF THE INVENTION

The present invention relates to semiconductor integrated circuits. More particularly, the invention provides a semiconductor memory that has integrated non-volatile and static random access memory cells. Although the invention has been applied to a single integrated circuit device in a memory application, there can be other alternatives, variations, and modifications. For example, the invention can be applied to embedded memory applications, including those with logic or micro circuits, and the like.

Semiconductor memory devices have been widely used in electronic systems to store data. There are generally two types of memories, including a non-volatile and volatile designs. The volatile memory, such as a Static Random Access Memory (SRAM) or a Dynamic Random Access Memory (DRAM), loses its stored data if the power applied has been turned off. SRAMs and DRAMs often include a multitude of memory cells disposed in a two dimensional array. Due to its larger memory cell size, an SRAM is typically more expensive to manufacture than a DRAM. An SRAM typically, however, has a smaller read access time than a DRAM. Therefore, where fast access to data is needed, SRAMs are often used to store the data.

Non-volatile semiconductor memory devices are also well known. A non-volatile semiconductor memory device, such as flash Erasable Programmable Read Only Memory (Flash EPROM), Electrically Erasable Programmable Read Only Memory (EEPROM) or, Metal Nitride Oxide Semiconductor (MNOS), retains its charge even after the power applied thereto is turned off. Therefore, where loss of data due to power failure or termination is unacceptable, a non-volatile memory is used to store the data.

Unfortunately, the non-volatile semiconductor memory is typically slower to operate than a volatile memory. Therefore, where fast store and retrieval of data is required, the non-volatile memory is not typically used. Furthermore, the non-volatile memory often requires a high voltage, e.g., 12 volts, to program or erase. Such high voltages may cause a number of disadvantages. The high voltage increases the power consumption and thus shortens the lifetime of the battery powering the memory. The high voltage may degrade the ability of the memory to retain its charges due to hot-electron injection. The high voltage may cause the memory cells to be over-erased during erase cycles. Cell over-erase results in faulty readout of data stored in the memory cells.

The growth in demand for battery-operated portable electronic devices, such as cellular phones or personal organizers, has brought to the fore the need to dispose both volatile as well as non-volatile memories within the same portable device. When disposed in the same electronic device, the volatile memory is typically loaded with data during a configuration cycle. The volatile memory thus provides fast access to the stored data. To prevent loss of data in the event a power failure occurs, data stored in the volatile memory is often also loaded into the non-volatile memory either during the configuration cycle, or while the power failure is in progress. After power is restored, data stored in the non-volatile memory is read and stored in the non-volatile memory for future access. Unfortunately, most of the portable electronic devices may still require at least two devices, including the non-volatile and volatile, to carry out backup operations. Two devices are often required since each of the devices often rely on different process technologies, which are often incompatible with each other.

To increase the battery life and reduce the cost associated with disposing both non-volatile and volatile memory devices in the same electronic device, non-volatile SRAMs and non-volatile DRAMs have been developed. Such devices have the non-volatile characteristics of non-volatile memories, i.e., retain their charge during a power-off cycle, but provide the relatively fast access times of the volatile memories. As merely an example, FIG. 1 is a transistor schematic diagram of a prior art non-volatile DRAM 10. Non-volatile DRAM 10 includes transistors 12, 14, 16 and EEPROM cell 18. The control gate and the drain of EEPROM cell 18 form the DRAM capacitor. Transistors 12 and 14 are the DRAM transistors. Transistor 16 is the mode selection transistor and thus selects between the EEPROM and the DRAM mode.

FIG. 2 is a transistor schematic diagram of a prior art non-volatile SRAM 40. Non-volatile SRAM 40 includes transistors 42, 44, 46, 48, 50, 52, 54, 56, resistors 58, 60 and EEPROM memory cells 62, 64. Transistors 48, 50, 52, 54 and resistors 58, 60 form a static RAM cell. Transistors 42, 44, 46, 56 are select transistors coupling EEPROM memory cells 62 and 64 to the supply voltage Vcc and the static RAM cell. Transistors 48 and 54 couple the SRAM memory cell to the true and complement bitlines BL and \overline{BL}.

SRAMs and DRAMs known in the prior art suffer from the high voltage problems associated with non-volatile memories, as described above. Furthermore, prior art non-volatile SRAMs and DRAMs are relatively large and are thus expensive. For example, nearly one half of the semiconductor surface area in which non-volatile SRAM cell 40 ( see FIG. 3) is formed is due to the relatively large surface area of resistors 58 and 60.

Accordingly, a need continues to exist for a relatively small non-volatile RAM that consumes less power than those in the prior art, does not suffer from read errors caused by over-erase, and is not degraded due to hot-electron injection.

From the above, it is seen that improved memory devices are still desired.

### BRIEF SUMMARY OF THE INVENTION

According to the present invention, an improved memory device and method is provided. More particularly, the invention provides a semiconductor memory that has integrated non-volatile and static random access memory cells. Although the invention has been applied to a single integrated circuit device in a memory application, there can be other alternatives, variations, and modifications. For example, the invention can be applied to embedded memory applications, including those with logic or micro circuits, and the like.

In accordance with the present invention, a memory cell includes both non-volatile and RAM cells. The RAM cell includes first, second, third and fourth n-channel MOS transistors. The source terminals of the first and second MOS transistors are respectively coupled to the first and second nodes. The drain terminals of the first and second MOS transistors are respectively coupled to the true and complement bitlines associated with the memory cell. The gate terminals of the first and second MOS transistors are coupled to a first terminal of the memory cell. The drain terminals of the third and fourth MOS transistors are respectively coupled to the first and second nodes. The gate terminals of the third and fourth MOS transistors are respectively coupled to the second and first nodes. The source terminal of both the third and fourth MOS transistors are coupled to the ground terminal.

The non-volatile memory cell includes first and second MNOS transistors. The source terminals of both the first and second MNOS transistors are respectively coupled to the first and second nodes. The gate terminals of the first and second MNOS transistors are respectively coupled to a second terminal of the memory cell. The drain terminals of both the first and second MNOS transistors are coupled to a third terminal of the memory cell. The body terminals of both the first and second MNOS transistors are coupled to a fourth terminal of the memory cell. The first and second MNOS transistors form a differential pair of transistors.

The SRAM cell may be programmed during a programming cycle. During such a programming cycle, the true bitline associated with the SRAM cell is either set to supply voltage Vcc or to 0 volts. The complement bitline associated with the SRAM cell is set to a voltage opposite to that of the true bitline (i.e., 0 or Vcc). The first terminal of the memory cell is also raised to the Vcc supply voltage, thereby causing data to be stored in the SRAM cell. Data may be stored in the SRAM cell during a read cycle of the non-volatile memory cell if the non-volatile memory cell has been programmed.

To program the non-volatile memory cell while the power is being turned off or during a programming cycle, a high programming voltage Vpp is applied to the second terminal of the memory cell. The Vpp voltage is higher than the Vcc voltage. During such a programming, the third terminal of the memory cell is coupled to the ground terminal. The application of these voltages causes electrons to be injected and trapped in the nitride layer of the MNOS transistor whose source-to-drain voltage is 0. No electrons are injected and trapped in the nitride layer of the MNOS transistor whose source-to-drain voltage is not 0. The threshold voltage of the MNOS transistor with trapped electrons increases whereas the threshold voltage of the MNOS transistor with no trapped electrons does not increase. This completes the programming cycle.

As stated above, to reprogram the SRAM cell after power is restored, the Vcc supply voltage is applied to the third terminal of the memory cell. A read sensing voltage is applied to the second terminal of the memory cell. The read sensing voltage is smaller than the Vcc supply voltage and is so selected as to disable current flow or, in the alternative, cause relatively small current to flow in the MNOS that has trapped electrons. The MNOS transistor with no trapped electrons conducts a relatively larger current than the MNOS that has trapped electrons. This differential current flow causes the first and second nodes to be charged or discharged to their previous states, thereby causing the SRAM cell to be reprogrammed with data it had prior to power supply termination or failure. To erase the MNOS transistor having trapped charges, 0 volt is applied to the second and third terminals of the memory cell and the Vpp voltage is applied to the fourth terminal of the memory cell.

The accompanying drawings, which are incorporated in and form part of the specification, illustrate embodiments of the invention and, together with the description, sever to explain the principles of the invention.

### BRIEF DESCRIPTION OF THE DRAWINGS

FIG. 1 is a simplified transistor schematic diagram of a non-volatile DRAM, as known in the prior art;

FIG. 2 is a simplified transistor schematic diagram of a non-volatile SRAM, as known in the prior art;

FIG. 3 is a simplified transistor schematic diagram of a memory cell having both SRAM and non-volatile memory cells, in accordance with one embodiment of the present invention;

FIG. 4A is a simplified timing diagram of the SRAM memory cell of FIG. 3 during a write cycle;

FIG. 4B is a simplified timing diagram of the SRAM memory cell of FIG. 3 during a read cycle;

FIG. 5 is a cross-sectional view of a MNOS transistor disposed in the memory cell of FIG. 3, in accordance with one embodiment of the present invention;

FIG. 6 shows the drain-to-source current vs. the gate-to-source voltage of the MNOS transistor of FIG. 5 before and after programming.

### DETAILED DESCRIPTION OF THE INVENTION

According to the present invention, an improved memory device and method is provided. More particularly, the invention provides a semiconductor memory that has integrated non-volatile and static random access memory cells. Although the invention has been applied to a single integrated circuit device in a memory application, there can be other alternatives, variations, and modifications. For example, the invention can be applied to embedded memory applications, including those with logic or micro circuits, and the like.

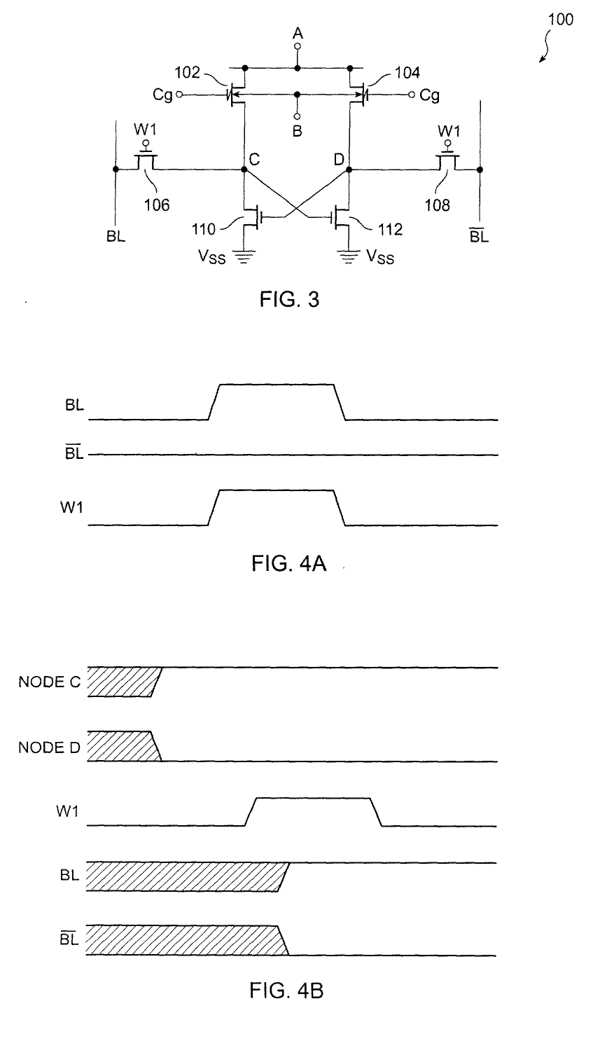

FIG. 3 is a transistor schematic diagram of memory cell 100, in accordance with one embodiment of the present invention. This diagram is merely an example, which should not unduly limit the scope of the claims herein. One of ordinary skill in the art would recognize many other variations, modifications, and alternatives. Memory cell 100 includes N-channel MNOS transistors 102, 104 which form a differential non-volatile memory cell, and N-channel Metal-Oxide-Semiconductor (MOS) transistors 106, 108, 110 and 112 which form a SRAM cell. Memory cell 100 may be part of a memory array (not shown) disposed in a semiconductor Integrated Circuit (IC) adapted, among other functions, to store and supply the stored data.

The gate terminals of both MOS transistors 106 and 108 are coupled to input terminal W1 of memory cell 100. The drain terminals of MOS transistor 106, 108 are respectively coupled to bitlines BL and \overline{BL} associated with the memory cell. The source terminals of MOS transistor 106, 108 are respectively coupled to nodes C and D. The drain, gate and source terminals of MOS transistor 110 are respectively coupled to node C, node D and the Vss terminal (i.e., the ground terminal). The drain, gate and source terminals of MOS transistor 112 are respectively coupled to node D, node C and the Vss terminal.

The gate terminals of MNOS transistors 102, 104 are coupled to input terminal Cg of the memory cell 100. The drain terminals of MNOS transistors 102, 104 are coupled to input terminal A of memory cell 100. The body (i.e., the bulk) terminals of MNOS transistors 102, 104 are coupled to input terminal B of memory cell 100. The source terminals of MNOS transistors 102, 104 are respectively coupled to nodes C and D. The operation of memory cell 100 is described next.

Programming the SRAM Cell

MOS transistors 106, 108, 110 and 112 form an SRAM cell. To store a 1 in this SRAM cell, bitline BL is raised to supply voltage Vcc and bitline \overline{BL} is pulled to the Vss voltage, i.e., to 0 volt. In some embodiment of the present invention, supply voltage Vcc is between 1.2 to 5.5 volts. Supply voltage Vcc is also applied to control terminal W1 of memory cell 100. Because transistor 106 is in a conducting state, node C is raised to voltage Vcc−Vt, where Vt is threshold voltage of any of the MOS transistors 106, 108, 110 and 112. Similarly, because MOS transistor 108 is in a conducting state, node D is pulled to 0 volts (i.e., the voltage present on bitline \overline{BL}). Therefore, N-channel transistor 112 is turned on and N-channel transistor 110 is turned off. Because N-channel transistor 112 is turned on, node D is also pulled to the Vss potential via transistor 112, thereby ensuring that transistors 110 remains off. Nodes C and D maintain their respective voltages, Vcc−Vt and 0, even after transistors 106 and 108 are turned off to decouple bitlines BL and \overline{BL} from nodes C and D.

To store a 0 in the SRAM cell, bitline BL is pulled to the Vss voltage and bitline \overline{BL} is raised to the Vcc voltage. Voltage Vcc is also applied to terminal W1 of memory cell 100. Because transistor 108 is in a conducting state, node D is raised to voltage Vcc−Vt. Similarly, because MOS transistor 106 is in a conducting state, node C is pulled to 0 volts (i.e., the voltage present on bitline BL). Therefore, N-channel transistor 110 is turned on and N-channel transistor 112 is turned off. Because N-channel transistor 110 is turned on, node C is also pulled to the Vss voltage via transistor 110, thereby ensuring that transistor 112 remains off.

To ensure that nodes C and D maintain their respective voltages, 0 and Vcc−Vt, after the programming cycle, a relatively small voltage, e.g. 0.2 to 2 volts, is applied to terminal Cg to maintain MNOS transistors 102, 104 in subthreshold regions. Because both MNOS transistors 102, 104 are maintained in subthreshold regions, a small subthreshold current flows in each of these transistors supplying charges to nodes C and D. In other words, MNOS transistors 102, 104 while in subthreshold regions act as load resistors to ensure that the SRAM cell does not lose its data. In other embodiments, transistors 106 and 108 are turned on periodically during refresh cycles to ensure that the SRAM cell does not lose its data

FIG. 4A is a simplified timing diagram of the voltages applied to bitlines BL, \overline{BL} as well as to input terminal W1 of memory cell 100 during a programming cycle of the SRAM cell. In accordance with FIG. 4A, bit line BL and input terminal W1 are raised to supply voltage Vcc while \overline{BL} is maintained at 0volts. Accordingly, node C is charged to supply voltage Vcc and node D is pulled to the ground voltage. The voltages at nodes C and D are maintained at these values either via subthreshold currents that flow through MNOS transistors 102, 104 or by periodically raising the voltage at terminal W1 to coupled nodes C and D to bitlines BL and \overline{BL}, as described above.

FIG. 4B is a simplified timing diagram of the voltage applied to input terminal W1 of memory cell 100 during a read cycle of the SRAM cell. In accordance with FIG. 4B, input terminal W1 is raised to supply voltage Vcc, thereby coupling nodes C and D to bitlines BL and \overline{BL}, respectively. Because nodes C and D respectively have high and low stored charges, bitlines BL and \overline{BL} are respectively raised to high and low voltages.

Programming the Non-Volatile Memory Cells

In accordance with the present invention, if the Vcc voltage supplied by, e.g. a battery, reduces below a certain value, or if there is an abrupt failure in the supply of voltage Vcc or if otherwise desired, data stored in the SRAM cell of memory cell 100 is stored in the non-volatile memory cell of memory cell 100. To achieve this, for example, a capacitor is used to store charges while voltage supply is being turned off. The charges stored in the capacitor are used by a high voltage generator circuit to generate the voltages required to operate the non-volatile memory cell. While the power supply reduction or failure occurs, data stored in the SRAM cell is loaded and stored in the non-volatile memory cell of memory cell 100. MNOS transistor pair 102, 104 operate differentially in that if one of them is programmed, the other one is not. Therefore, during a readout of their data, if one of the MNOS transistors supplies a 1, the other one supplies a 0.

Assume that the SRAM is loaded with a 1, and therefore the voltages present on nodes C and D are at high and low levels respectively. To store this data in the non-volatile memory cell, 0 volt is applied to both input terminal A and B of memory cell 100. Furthermore, a relatively high programming voltage Vpp (e.g., 7 volts) is applied to the terminal Cg of memory cell 100. Because there is a voltage difference between the drain and source terminals of MNOS 102 and because the gate terminal of MNOS 102 receives the Vpp voltage, current flows between the source and drain terminals of MNOS transistor 102. Therefore, no Fowler-Nordheim tunneling of electrons occurs in MNOS 102. Accordingly, MNOS 102 maintains its previous discharge state and thus its threshold voltage remains unchanged.

Because both the drain and source terminals of MNOS 104 are at 0 volt, no current flows between the source and drain terminals of MNOS transistor 104. Accordingly, a Fowler-Nordheim tunneling occurs in MONS 104, thereby causing electrons to be injected and trapped in the insulating nitride layer of MNOS 104. The trapping of electrons in the insulating nitride layer of MNOS 104, in turn, increase its threshold voltage. Therefore, MNOS 104 is programmed (i.e., charged) whereas MNOS 102 is not programmed (i.e., is not charged). Therefore, during each non-volatile memory cell programming cycle only one of the MNOS transistors of memory cell 100 is programmed. The differential programming provides advantages that are described further below.

The charges remain trapped in MNOS 104 after power is turned off. Therefore, MNOS 104 maintains its higher threshold even after power is turned off. The increase in the threshold voltage of MNOS 104 is used to restore the programming state of the SRAM cell when the power is subsequently restored.

Reprogramming of the SRAM Cell

After power is restored, the SRAM cell is reloaded (i.e., reprogrammed) with data that it had prior to the power-off. As described above, this data is stored in the non-volatile memory cell during the power-off. To reload this data in the SRAM cell, the Vcc voltage is applied to the terminal A of memory cell 100. Terminal B of memory cell 100 is pulled to the ground potential. A relatively small sensing voltage (i.e., less than the Vcc voltage) is applied to terminal Cg. The sensing voltage is selected so as to be larger than the threshold voltage of the uncharged MNOS transistor 102.

Because the gate-to-source voltage of MNOS transistor 102 is greater than its threshold voltage and because of the presence of a voltage across the drain and source terminals of MNOS 102, a current flows between drain and source terminals of MNOS transistor 102. Depending on the magnitude of the increase in the threshold voltage of MNOS transistor 104, either MNOS transistor 104 conducts no current or, alternatively conducts a current with a magnitude that is smaller than that conducted by MNOS transistor 102.

The difference between the magnitude of the current flowing through MNOS transistor 102 and that, if any, flowing through MNOS transistor 104, results in differential charging of nodes C and D. Because node C is charged at a higher rate than node D, MOS transistor 112 is turned on, thereby pulling node D to the ground potential. Therefore, transistors 110 is turned off, enabling node C to be pulled high to the Vcc voltage. Because nodes C and D are charged to the Vcc and the ground potential, respectively, data is restored in the SRAM cell.

As described above, during the power restore operation when data stored in MNOS transistors 102 and 104 are read out, the current flow through MNOS transistors 102 and 104 is differential. Therefore, any changes in the threshold voltages of MNOS transistor 102 and MNOS transistor 104 due to over-erase also occurs differentially. The differential current flow through MNOS transistors 102 and 104, in accordance with the present invention, minimizes any data retention or read errors that may occur as a result of overerasing MNOS transistors 102 and 104 during erase cycles.

Erasing the Non-Volatile Memory Cells

To erase the non-volatile memory cell, terminals A and Cg of memory cell 100 are pulled to the Vss voltage. The Vpp voltage is applied to terminal B of memory cell 100. The high voltage applied to terminal B, removes the charges trapped in the nitride layer of MNOS transistor 104, thereby causing the threshed voltage of MNOS transistor 104 to be reduced.

As described above, in some embodiments of the present invention, the voltages applied to memory cell 100 are as follows: Vpp is between 4 to 9 volts; Vcc is between 1.8 to 5.5 volts; and the sensing voltage is between 0.5 and 3 volts. Because the Vpp voltage applied to memory cell 100 is lower than those required by conventional Flash EPROM or EEPROM cells, memory cell 100 (1) advantageously consumes relatively smaller power and (2) advantageously has less hot-electron induced reliability problems than conventional Flash EPROM or EEPROM cells.

MNOS Transistor

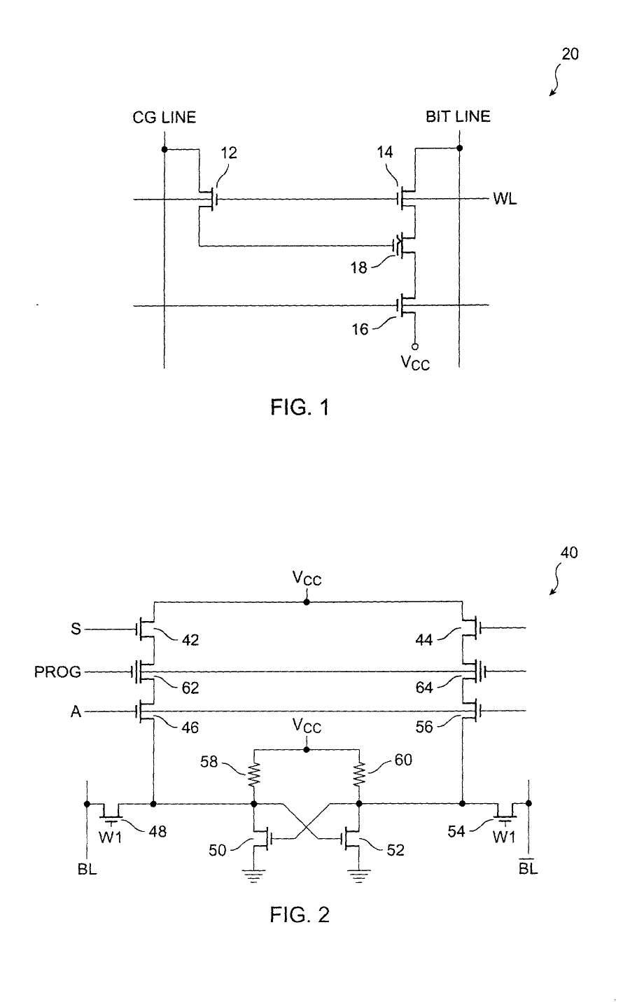

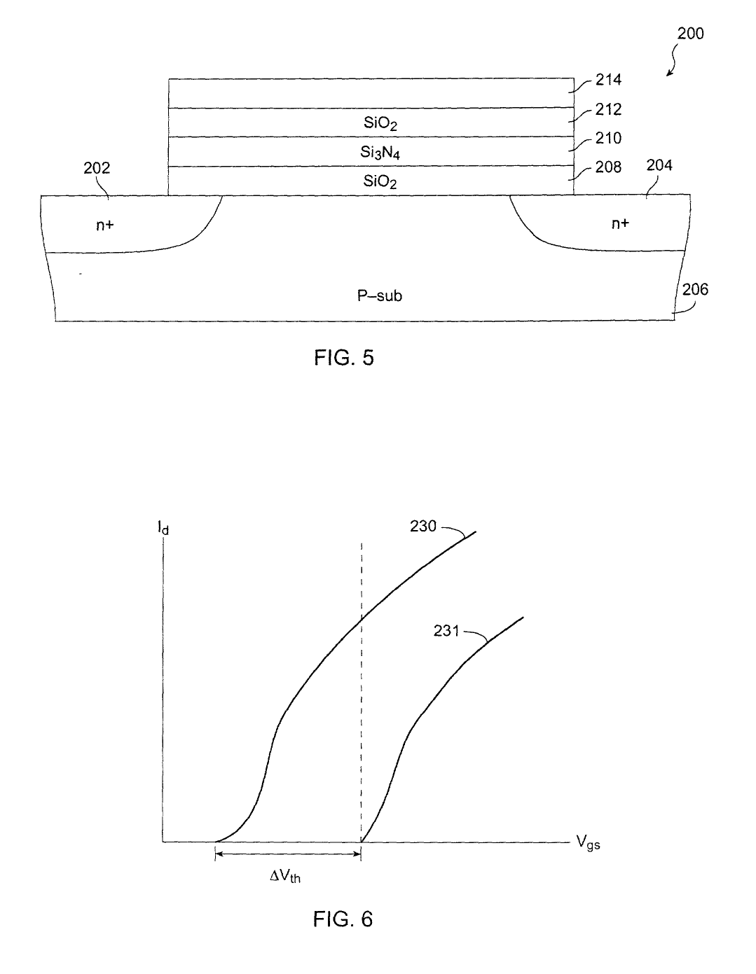

FIG. 5 is a cross-sectional view of an MNOS memory transistor 200 (hereinafter MNOS 200) used in memory cell 100 of FIG. 1, according to an embodiment of the present invention. MNOS 200 includes, among other regions, n-type source region 202, n-type drain region 204, p-type substrate region 206, oxide layer 208, nitride layer 210, oxide layer 212, and gate region 214.

To program MNOS 200, the VPP voltage is applied between gate region 214 and substrate region 206, while at the same time a low voltage (e.g., 0 volt) is applied between source region 202 and drain region 204. The voltages so applied cause electrons to be injected from substrate region 206 to oxide layer 208 due to Fowler-Nordheim tunneling phenomenon. The injected electrons remain trapped in nitride layer 210 even after power is turned off. The trapped electrons, in turn, increase the threshold voltage of MNOS 200.

FIG. 6 shows the effect of the increase in the threshold voltage on MNOS 200's current conduction characteristics. Reference numerals 230 and 232 respectively designate the drain-current vs. gate-voltage of MNOS 200 before and after it is programmed. As seen from FIG. 6, the increase in the threshold voltage Vₜₕ reduces the drain current for each applied Gate voltage. In other words, a programmed MNOS memory conducts less current than a MNOS memory that has not been programmed. The reduction in the current conduction capability is used to determine whether an MNOS has been programmed, as described above.

The above embodiments of the present invention are illustrative and not limitative. The invention is not limited by the type of non-volatile memory transistor disposed in the memory cell of the present invention. Moreover, both N-channel and P-channel transistors may be used to from the SRAM as well as the non-volatile memory cells of the present invention. The invention is not limited by the type of integrated circuit in which the memory cell of the present invention is disposed. For example, the memory cell, in accordance with the present invention, may be disposed in a programmable logic device, a central processing unit, a memory having arrays of memory cells or any other IC which is adapted to store data.

While the invention is described in conjunction with the preferred embodiments, this description is not intended in any way as a limitation to the scope of the invention. Modifications, changes, and variations, which are apparent to those skilled in the art can be made in the arrangement, operation and details of construction of the invention disclosed herein without departing from the spirit and scope of the invention.

What is claimed is:

1. A integrated memory cell including volatile and non-volatile capabilities in a single cell, the integrated memory cell being one of a plurality cells provided in an array on an integrated circuit device, the single memory cell comprising:
a random access memory device adapted to store at least one bit of data, the random access memory comprising a first source/drain region, the one bit of data being stored in the random access memory while the random access memory is subjected to a predetermined power; and
a non-volatile memory device adapted to store at least one bit of data for use in the random access memory device, the non-volatile memory comprising a second source/drain region, the non-volatile memory being coupled to the random access memory device to form an integrated structure, the integrated structure being configured where the first source/drain and the second/source drain share a common region to allow the non-volatile memory device to share the one bit of data from either the random access memory or the non-volatile memory directly between the random access memory device and the non-volatile memory device.

2. The integrated memory cell of claim 1 wherein the random access memory is selected from a group consisting of SRAM, latched circuit, DRAM and FRAM.

3. The integrated memory cell of claim 1 wherein non-volatile memory device is a flash memory device.

4. The integrated memory cell of claim 1 wherein non-volatile memory device is an EEPROM or EPROM.

5. The integrated memory cell of claim 1 wherein non-volatile memory device is a MNOS (metal oxide nitride silicon) memory device.

6. The integrated memory cell of claim 1 wherein the use is a power off operation.

7. The integrated memory cell of claim 1 wherein the use is a back up operation.

8. The integrated memory cell of claim 1 wherein the common region comprises common source/drain region, the common source/drain region being configured to allow the non-volatile memory and the volatile memory to share the one bit of data between the non-volatile memory device or the volatile memory device.

9. A memory cell comprising:
a first MOS transistor having a first current carrying terminal coupled to a first node, a second current carrying terminal coupled to a first bitline associated with the memory cell, and a gate terminal coupled to a first terminal of the memory cell;
a second MOS transistor having a first current carrying terminal coupled to a second node, a second current carrying terminal coupled to a second bitline associated with the memory cell, and a gate terminal coupled to the first terminal of the memory cell;
a third MOS transistor having first and second current carrying terminals that are respectively coupled to the first node and a ground terminal, and a gate terminal that is coupled to the second node;
a fourth MOS transistor having first and second current carrying terminals that are respectively coupled to the second node and the ground terminal, and a gate terminal that is coupled to the first node;
a first non-volatile memory transistor having a gate terminal that is coupled to a second terminal of the memory cell, a first current carrying terminal coupled to a third terminal of the memory cell, a body terminal that is coupled to a fourth terminal of the memory cell, and a second current carrying terminal coupled to the first node; and
a second non-volatile memory transistor having a gate terminal that is coupled to the second terminal of the memory cell, a first current carrying terminal coupled to the third terminal of the memory cell, a body terminal that is coupled to the fourth terminal of the memory cell, and a second current carrying terminal coupled to the second node.

10. The memory cell of claim 9 wherein said first and second bitlines associated with the memory cell have complementary voltages.

11. The memory cell of claim 9 wherein the first and second nodes maintain their respective voltages after the first and second MOS transistors are turned off, wherein the first and second nodes receive their respective voltages from the first and second bitlines.

12. The memory cell of claim 9 wherein each of the first and second non-volatile memory transistors is selected from a group consisting of EEPROM, Flash EPROM, EPROM and MNOS transistors.

13. The memory cell of claim 9 wherein during a power-off cycle when the memory cell is not supplied with a voltage supply, the second terminal of the memory cell receives a voltage that is greater than the voltage supplied by the voltage supply.

14. The memory cell of claim 13 wherein each of said first and second non-volatile memory transistors is an MNOS transistor.

15. The memory cell of claim 14 wherein during the power-off cycle the third and the fourth terminals of the memory cell receive 0 volt.

16. The memory cell of claim 15 wherein during the power-off cycle one of the first and second MNOS transistors traps electrons in its nitride layer.

17. The memory cell of claim 16 wherein following the power-off cycle and after the memory cell is supplied with the voltage supply, the fourth terminal of the memory cell receives 0 volt, the third terminal of the memory receives the supply voltage, and the second terminal of the memory cell receives a voltage that is between 0 volts and the supply voltage, thereby supplying the first and second nodes with voltages they had prior to the power-off cycle.

18. The memory cell of claim 17 wherein the trapped electrons are untrapped by applying 0 volt to both the third and fourth terminals of the memory cell, and by applying a voltage that is greater than the supply voltage to the fourth terminal of the memory cell.

19. The memory cell of claim 9 wherein said first and second non-volatile memory transistors are operated in subthreshold regions.

20. The memory cell of claim 19 wherein said first and second MOS transistors are periodically turned on.

21. A method comprising:
forming a random access memory cell having first and second nodes;
forming a first non-volatile memory transistor coupled to the first node; and
forming a second non-volatile memory transistor coupled to the second node.

22. The method of claim 21 further comprising:
receiving complementary voltages by said first and second nodes.

23. The method of claim 21 wherein each of the first and second non-volatile memory transistors is selected from a group consisting of EEPROM, Flash EPROM, EPROM and MNOS transistors.

24. The method of claim 21 further comprising:
receiving data from the random access memory; and
storing the received data in one of the first and second non-volatile memory transistors during a power-off.

25. A method comprising:
supplying data stored in a random access memory; and
storing the data supplied by the random access memory differentially in a non-volatile memory.
